(19) United States
(12) Patent Application Publication
(10) Pub. No.: US 2008/0048310 A1
(43) Pub. Date: Feb. 28, 2008

(54) Carrier Board Structure Embedded with Semiconductor Component and Method for Fabricating the Carrier Board Structure

(75) Inventor: Zhao Chong Zeng, Hsin-chu (TW)

Correspondence Address: FULBRIGHT AND JAWORSKI LLP, 555 S. FLOWER STREET, 41ST FLOOR, LOS ANGELES, CA, 90071, US

(73) Assignee: PHOENIX PRECISION TECHNOLOGY CORPORATION, Hsin-chu (TW)

(21) Appl. No.: 11/467,286

(22) Filed: Aug. 25, 2006

(51) Int. Cl. H01L 23/48; H01L 23/12

(52) U.S. Cl. 257/690; 257/700

(57) ABSTRACT

A carrier board structure with a semiconductor component embedded therein and a method for fabricating the same are proposed. The method provides at least one semiconductor component and a carrier having a first surface and a second surface opposed to the first surface and at least one through hole. The semiconductor component has an active surface having a plurality of electrode pads and an inactive surface, opposed to the active surface, having a plurality of recesses. An adhesive layer is formed on the second surface of the carrier for sealing an end of through hole of the carrier. Thus, the semiconductor component can be mounted in the through hole of the carrier, and the inactive surface can be mounted on the adhesive layer, as well as the adhesive layer fills in the recess of semiconductor component and the gap between the through hole of carrier board and semiconductor component. Owing to reduce the possibility of separation between the semiconductor component and the adhesive layer, the integral connection between the semiconductor component and carrier are enhanced.

### FIELD OF THE INVENTION

The present invention relates to a carrier board structure embedded with semiconductor components and a method for fabricating the carrier board structure, and more particularly, to a carrier board structure having a carrier and a semiconductor component having an inactive surface formed with a plurality of recesses and embedded into a through hole of the carrier, and a method for fabricating the carrier board structure.

### BACKGROUND OF THE INVENTION

With increasing demand for lighter, thinner, shorter and smaller electronic products, a highly integrated package board embedded with a semiconductor component is proposed to meet this demand.

FIG. 1 is a cross sectional view of a carrier board structure embedded with a semiconductor component 11 according to the prior art. In addition to the semiconductor component 11, the carrier board structure further comprises a carrier 12 and an adhesive layer 13. The carrier board 12 has a first surface 12a, a second surface 12b and a through hole 120 through the first surface 12a and the second surface 12b. The adhesive layer 13 is formed on the second surface 12b. The semiconductor component 11 has an active-surface 11a provided with a plurality of electrode pads, and an inactive surface 11b opposed to the active-surface 11a and mounted on the adhesive layer 13. The adhesive layer 13 is further filled in gaps between the through hole 120 of carrier 12 and semiconductor component 11. Thus, the semiconductor component 11 can be fixed in the through hole 120 of the carrier 12.

However, the semiconductor component 11 embedded in the carrier 12 is fixed by the adhesive layer 13 to the through hole 120. Thus, because the adhesive layer 13 is adhered to the inactive surface 11b, which is very smooth, the semiconductor component 11 cannot be fixed tightly to the adhesive layer 13. Therefore, the semiconductor component 11 is easily separated from the adhesive layer 13 in subsequent fabricating processes because of the diversity of their coefficient of thermal expansions (CTE), and a semiconductor product embedded in the carrier board structure has poor quality.

Therefore, how to ensure that the semiconductor component 11 can be fixed tightly to the carrier 12 has becoming one of the most urgent errands in the art.

### SUMMARY OF THE INVENTION

In light of the above drawbacks of the prior art, an objective of the present invention is to provide a carrier board structure embedded with a semiconductor component and a method for fabricating the carrier board structure, to ensure that the semiconductor component can be fixed tightly to an adhesive layer of the carrier board structure.

Another objective of the present invention is to provide a carrier board structure embedded with a semiconductor component and a method for fabricating the carrier board structure, which can be used in the following frablicating process, so as to improve product yield and reliability.

In accordance with the above and other objectives, the present invention proposes a method for fabricating a carrier board structure embedded with a semiconductor component. The method includes providing a carrier and the semiconductor component, the carrier having a first surface, a second surface and has a through hole through the first surface and the second surface, the semiconductor component having an active surface provided with a plurality of electrode pads and an inactive surface opposed to the active surface and provided with a plurality of recesses; mounting an adhesive layer on the second surface of the carrier to seal one end of the through hole; and mounting the semiconductor component into the through hole of the carrier, the inactive surface having the recesses being mounted on the adhesive layer, the adhesive layer further filling the recesses of the semiconductor component and gaps between the through hole of the carrier and the semiconductor component.

The method further includes forming a protecting layer such as a metal layer on the adhesive layer.

At least one of the recesses of the semiconductor component is a slot formed by a cutter cutting or an etching. The slot is one selected from the group consisting of a transverse slot, a longitudinal slot, a sidelong slot and a cross slot. The semiconductor component is an active component or a passive component. The carrier is an insulating board, a metal board or a circuit board having circuitry. The adhesive layer is a dielectric layer or an adhesive material.

The method further includes forming a circuit build-up structure on the first surface of the carrier and the active surface of the semiconductor component, a plurality of conductive structures formed in the circuit build-up structure and electrically connected to the electrode pads of the semiconductor component, and a plurality of electrically conductive pads formed on the circuit build-up structure. A solder mask is formed on the circuit build-up structure. The solder mask has a plurality of openings for exposure of the electronically conductive pads of the circuit build-up structure. The circuit build-up structure includes a dielectric layer, a circuit layer stacked on the dielectric layer and a conductive structure formed in the dielectric layer.

The carrier board structure embedded with a semiconductor component is proposed accordingly. The carrier board structure includes a carrier having a first surface, a second surface and a through hole through the first surface and the second surface; the semiconductor component, which is mounted in the through hole and has an active surface provided with a plurality of electrode pads and an inactive surface opposed to the active surface and provided with a plurality of recesses; and an adhesive layer mounted on the second surface of the carrier and the inactive surface of the semiconductor component, and filled in the recesses of the semiconductor component and gaps between the through hole of the carrier and the semiconductor component.

At least one of the recesses of the semiconductor component is a slot formed by a cutter cutting or an etching. The slot is one selected from the group consisting of a transverse slot, a longitudinal slot, a sidelong slot and a cross slot.

Therefore, in the carrier board structure embedded with the semiconductor component and the method for fabricating the carrier board structure, a plurality of recesses are firstly formed on the inactive surface of the semiconductor component, then, the adhesive layer is filled in the recesses of the semiconductor component and the gaps between the through hole and the semiconductor component, so as to fix the semiconductor component in the through hole of the carrier. Because the inactive surface of the semiconductor component has the recesses, so a connection area between the semiconductor component and the adhesive layer is increased equivalently, scilicet, the integral connection between the semiconductor component and carrier are enhanced. So, in following fabricating process and reliability test, there is no separation happened in the carrier caused by the difference of CTE.

### BRIEF DESCRIPTION OF THE DRAWINGS

The present invention can be more full, understood by reading the following detailed description of the preferred embodiments, with reference made to the accompanying drawings, wherein:

FIG. 1 (PRIOR ART) is a cross sectional view of a carrier board structure embedded with a semiconductor component according to the prior art; and

FIGS. 2A to 2E are five cross sectional views demonstrating a method for fabricating a carrier board structure embedded with a semiconductor component of the preferred embodiment according to the present invention.

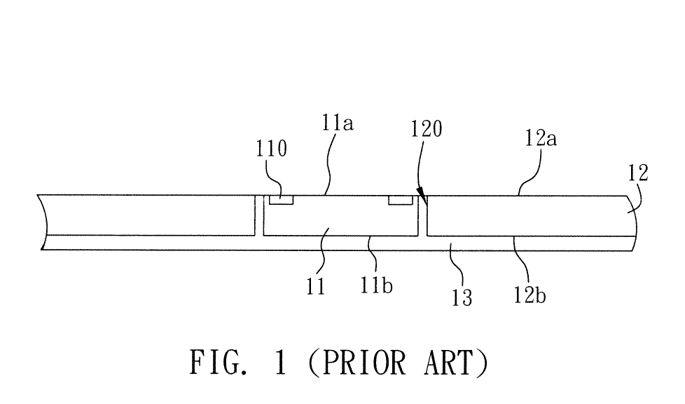

### DETAILED DESCRIPTION OF THE PREFERRED EMBODIMENTS

Hereunder, embodiments of the present invention will be described in full detail with reference to the accompanying drawings. Those skilled in the art can easily understand other advantages and functions of this invention by this present specification disclosing.

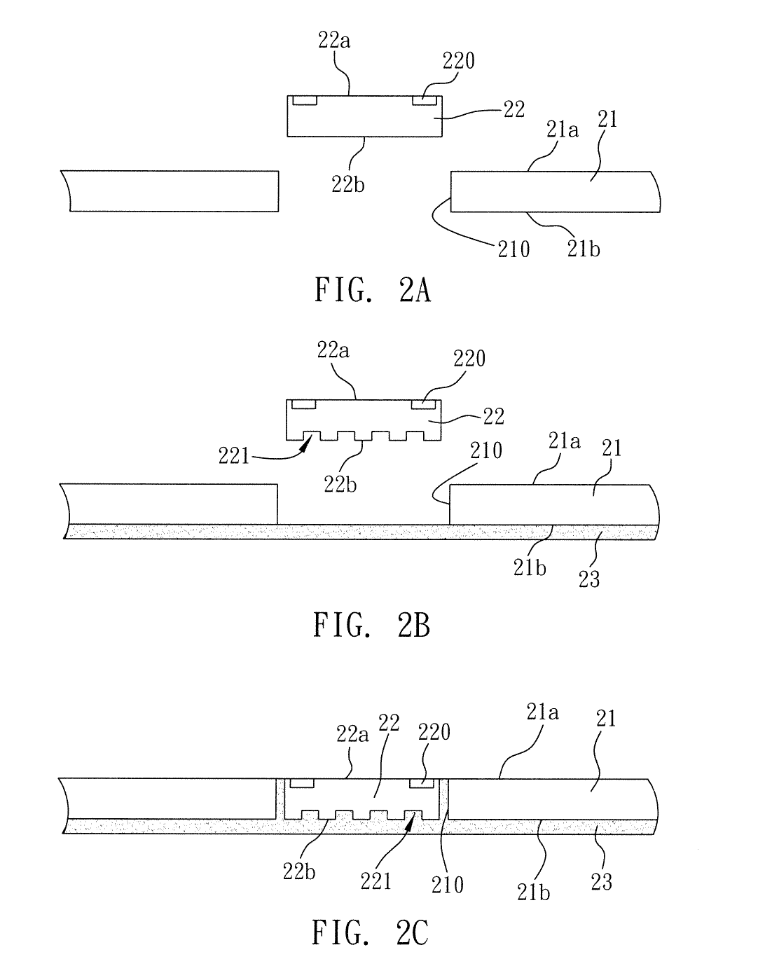

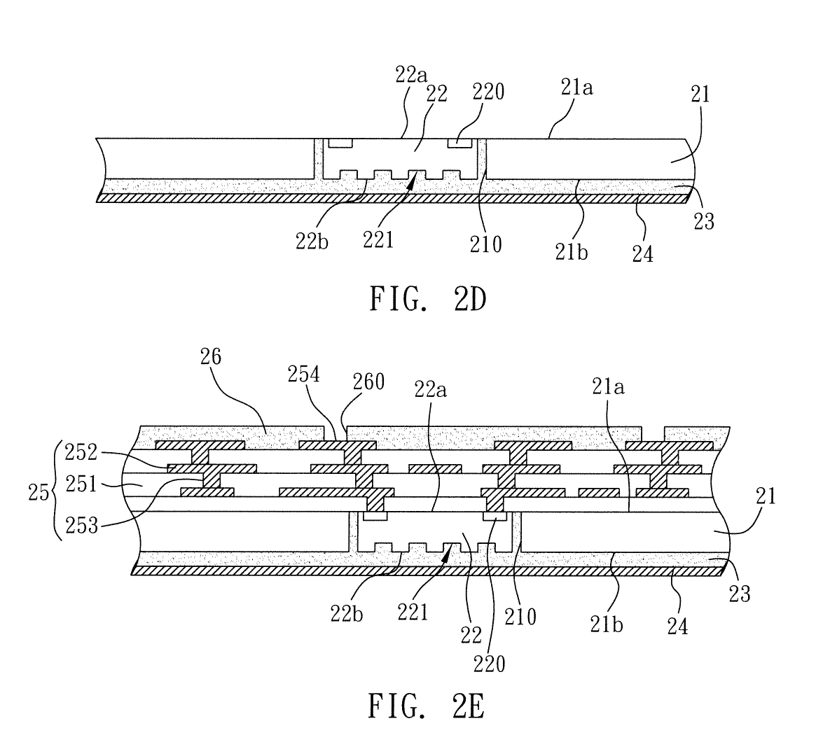

FIGS. 2A to 2E are five cross sectional views demonstrating a method for fabricating a carrier board structure embedded with a semiconductor component of the preferred embodiment according to the present invention.

Referring to FIGS. 2A and 2B a carrier 21 and a semiconductor component 22 are provided. The carrier 21 has a first surface 21a, a second surface 21b opposed to the first surface 21a, and a through hole 210 through the first surface 21a and second surface 21b. The semiconductor component 22 has an active surface 22a and an inactive surface 22b. The active surface 22a is provided with a plurality of electrode pads 220. According to the preferred embodiment, the semiconductor component 22 is an active component or a passive component, and the carrier 21 is an insulating board, a metal board or a circuit board with circuitry.

A plurality of recesses 221 are formed on the inactive surface 22b of semiconductor component 22. An adhesive layer 23 is formed on the second surface 21b of the carrier 21 and the inactive surface 22b of the semiconductor component 22 for sealing one end of the through hole 210. The adhesive layer 23 is a dielectric layer or an adhesive material.

At least one of the recesses 221 formed on the inactive surface 22b of the semiconductor component 22 is a slot, which is formed by mechanical or laser cutter cutting or an etching. The slot is, but not limited to, a transverse slot, longitudinal slot, sidelong slot or a cross slot. However, the size and position of the slot may be flexibly exchanged according to practical requirements.

Referring to FIG. 2C, the semiconductor component 22 is mounted into the through hole 210 of the carrier 21, and the inactive surface 22b is mounted on the adhesive layer 23. A protecting layer (not shown in FIG. 2C) is further formed on the active surface 22a of the semiconductor component 22. The adhesive layer 23 is filled in the recesses 221 of the semiconductor component 22 and gaps between the through hole 220 and the semiconductor component 22 by a laminating process. Therefore, the semiconductor component 22 can be fixed tightly in the through hole 220. Then, the protecting layer is removed to expose the active surface 22a of the semiconductor component 22.

The inactive surface 22b has the recesses 221, so as to enhance the connection between the semiconductor component 22 and the adhesive layer 23, and avoid separation in the carrier 21 because of the difference of CTE.

Referring to FIG. 2D, the protecting layer 24 is further formed on the adhesive layer 23. The protecting layer 24 is a metal layer.

Referring to FIG. 2E, a circuit build-up structure 25 is further formed on the first surface 21a of the carrier 21 and the active surface 22a of the semiconductor component 22. The circuit build-up structure 25 comprises a dielectric layer 251, a circuit layer 252 stacked on the dielectric layer 251, and a conductive structure 253 formed in the dielectric layer 251 and electrically connected to the electrode pads 220. A plurality of electrically conductive pads 254 are formed on the circuit build-up structure 25. A solder mask 26 is further formed on the circuit build-up structure 25. The solder mask 26 has a plurality of openings 260 for exposure of the electrically conductive pads 254, which are used for electrically connecting to conductive element s(not shown in FIG. 2E), by which the carrier board structure of the present invention can be electrically connected to the other electronic devices.

Accordingly, as shown in FIG. 2D, a carrier board structure fabricated by the method of the present invention includes a carrier 20 having a first surface 21a, a second surface 21b opposed to the first surface 21a, and a through hole 210 through the first surface 21a and the second surface 21b. The carrier 20 is an insulting board, metal board or circuit board with circuitry. The carrier board structure further includes a semiconductor component 22 having an active surface 22a and an inactive surface 22b opposed to the surface 22a. The active surface 22a is provided with a plurality of electrode pads 220, and the inactive surface 22b is provided with a plurality of recesses 221. The semiconductor component 22 is an active component or a passive component. The semiconductor component 22 is mounted in the through hole 210 by the inactive surface 22b. The carrier board structure further includes an adhesive layer 23 formed on the second surface 21b of the carrier 21 and the inactive surface 22b of the semiconductor component 22, and filled in the recesses 221 of the semiconductor component 22 and the gaps between the through hole 210 and the semiconductor component 22, for fixing the semiconductor component 22 in the through hole 210.

Therefore, in the carrier board structure embedded semiconductor component therein and the method for fabricating the same, a plurality of recesses are firstly formed on the inactive surface of the semiconductor component, then, the semiconductor component can be fixed in the through hole of the carrier by the adhesive layer filling in the recesses of the semiconductor component and the gap between the through hole and the semiconductor component, thereby enhancing the connection between the semiconductor component and adhesive layer, and improving the integral connection between the semiconductor component and carrier. So, in following fabricating process, such as circuit build-up process, and reliability test, there is no separation happened in the carrier caused by the difference of CTE, thereby improving the development of the carrier board structure with semiconductor component embedded therein.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A carrier board structure embedded with a semiconductor component, the carrier board structure comprising:
a carrier having a first surface, a second surface and a through hole through the first surface and the second surface;
the semiconductor component, which is mounted in the through hole and has an active surface provided with a plurality of electrode pads and an inactive surface opposed to the active surface and provided with a plurality of recesses; and
an adhesive layer mounted on the second surface of the carrier and the inactive surface of the semiconductor component, and filled in the recesses of the semiconductor component and gaps between the through hole of the carrier and the semiconductor component.

2. The carrier board structure of claim 1 further comprising a protecting layer mounted on an outer surface of the adhesive layer.

3. The structure of claim structure of claim 2, wherein the protecting layer is a metal layer.

4. The structure of claim structure of claim 1, wherein the carrier is one selected from the group consisting of an insulating board, metal board and circuit board having circuitry.

5. The structure of claim structure of claim 1, wherein at least one of the recesses of the semiconductor component is a slot formed by one of a cutter cutting and an etching.

6. The structure of claim structure of claim 5, wherein the slot is one selected from the group consisting of a transverse slot, a longitudinal slot, a sidelong slot and a cross slot.

7. The structure of claim structure of claim 1, wherein the semiconductor component is one selected from the group consisting of an active component and a passive component.

8. The structure of claim structure of claim 1 further comprising a circuit build-up structure formed on the first surface of the carrier and the active surface of the semiconductor component, a plurality of conductive structures formed in the circuit build-up structure and electrically connected to the electrode pads of the semiconductor component, and a plurality of electrically conductive pads formed on the circuit build-up structure.

9. The structure of claim structure of claim 8 further comprising a solder mask formed on the circuit build-up structure, the solder mask having a plurality of openings for exposure of the electrically conductive pads.

10. The structure of claim structure of claim 8, wherein the circuit build-up structure comprises a dielectric layer, a circuit layer stacked on the dielectric layer, and a conductive structure formed in the dielectric layer.

11. A method for fabricating a carrier board structure embedded with a semiconductor component, the method comprising:
providing a carrier and the semiconductor component, the carrier having a first surface, a second surface and has a through hole through the first surface and the second surface, the semiconductor component having an active surface provided with a plurality of electrode pads and an inactive surface opposed to the active surface and provided with a plurality of recesses;
mounting an adhesive layer on the second surface of the carrier to seal one end of the through hole; and
mounting the semiconductor component into the through hole of the carrier, the inactive surface having the recesses being mounted on the adhesive layer, the adhesive layer further filling the recesses of the semiconductor component and gaps between the through hole of the carrier and the semiconductor component.

12. The method of claim 11 further comprising forming a protecting layer on the adhesive layer.

13. The method of claim 12, wherein the protecting layer is a metal layer.

14. The method of claim 11, wherein the carrier is one selected from the group consisting of an insulating board, metal board and circuit board having circuitry.

15. The method of claim 11, wherein the at least one of the recesses of the semiconductor component is a slot formed by one of a cutter cutting and an etching.

16. The method of claim 15, wherein the slot is one selected from the group consisting of a transverse slot, a longitudinal slot, a sidelong slot and a cross slot.

17. The method of claim 11, wherein the semiconductor component is one of selected from the group consisting an active component and a passive component.

18. The method of claim 11 further comprising forming a circuit build-up structure on the first surface of the carrier and the active surface of the semiconductor component, a plurality of conductive structures formed in the circuit build-up structure and electrically connected to the electrode pads of the semiconductor component, and a plurality of electrically conductive pads formed on the circuit build-up structure.

19. The method of claim 18 further comprising forming a solder mask on the circuit build-up structure, the solder mask having a plurality of openings for exposure of the electrically conductive pads of the circuit build-up structure.

20. The method of claim 18, wherein the circuit build-up structure comprises a dielectric layer, a circuit layer stacked on the dielectric layer and a conductive structure formed in the dielectric layer.
